(19) United States
(12) Patent Application Publication
(10) Pub. No.: US 2026/0332096 A1
(43) Pub. Date: Oct. 22, 2026

(54) RELAXATION OSCILLATOR WITH AN OFFSET RESISTOR

(71) Applicant: Nordic Semiconductor ASA, Trondheim (NO)

(72) Inventors: Lukasz FARIAN, Trondheim (NO); Hans Ola DAHL, Trondheim (NO)

(21) Appl. No.: 19/105,545

(22) PCT Filed: Aug. 23, 2023
(86) PCT No.: PCT/EP2023/073160

§ 371 Date: Feb. 21, 2025

(30) Foreign Application Priority Data
Aug. 24, 2022 (FI) 20225748

(51) Int. Cl. H03B 5/04; H03B 5/20

(52) U.S. Cl. CPC H03B 5/04; H03B 5/20

(57) ABSTRACT

According to an aspect, there is provided a relaxation oscillator (100) comprising first (101, 11) and second (102, 12) current sources and a comparator (103) having a first input (103−) connected to the first current source, a second input (103+) connected to the second current source and an output. One of the first and second inputs is an inverting input and other one of the first and second inputs is a non-inverting input. The relaxation oscillator further comprises a resistive circuit (110) connected between the first input of the comparator and the ground. The resistive circuit comprises at least a first resistor (R) and a capacitor charging circuit (111) connected between the second input of the comparator and the ground. The capacitor charging circuit comprises a capacitor (105, C), a second resistor (107, R0) connected in series with the capacitor and a switch (106) connected in parallel with the capacitor. The switch is configured to be controlled based on the output of the comparator.

### TECHNICAL FIELD

Various example embodiments relate to relaxation oscillators.

### BACKGROUND

A relaxation oscillator is a non-linear electronic oscillator circuit for generating a non-sinusoidal (e.g., a square wave) periodic output signal. The operation of relaxation oscillator is based on periodic charging and discharging of a capacitor. For most relaxation oscillator applications, it is desirable to have zero or at least low temperature coefficient meaning that the output of the relaxation oscillator is not temperature-dependent or is only slightly temperature dependent. While the capacitor of the relaxation oscillator has typically negligible (i.e., close-to-zero) temperature coefficient, the temperature coefficient of the sheet resistance of the relaxation oscillator often has considerably larger positive value. To overcome this issue, a mix of resistors with positive and negative temperature coefficient may be used in the relaxation oscillator to obtain clock with flat temperature coefficient. However, typical Complementary Metal Oxide Semiconductor (CMOS) manufacturing processes do not offer resistors with negative temperature coefficients. Even if such resistors are offered in the CMOS manufacturing process, the inclusion of such resistors is costly and considerably complicates the manufacturing process as additional masks need to be applied during the manufacturing process.

### BRIEF DESCRIPTION

According to a first aspect, there is provided a relaxation oscillator comprising:
first and second current sources;
a comparator having a first input connected to the first current source, a second input connected to the second current source and an output, wherein one of the first and second inputs is an inverting input and other one of the first and second inputs is a non-inverting input;
a resistive circuit connected between the first input of the comparator and the ground, wherein the resistive circuit comprises at least a first resistor; and
a capacitor charging circuit connected between the second input of the comparator and the ground, wherein the capacitor charging circuit comprises a capacitor, a second resistor connected in series with the capacitor and a switch connected in parallel with the capacitor, the switch being configured to be controlled based on the output of the comparator.

According to a second aspect, there is provided a differential relaxation oscillator comprising:
first, second and third current sources;
a first comparator having a first input connected to the first current source, a second input connected to the third current source and an output, wherein one of the first and second inputs of the first comparator is an inverting input and other one of the first and second inputs of the first comparator is a non-inverting input;
a second comparator having a first input connected to the first current source, a second input connected to the second current source and an output, wherein one of the first and second inputs of the second comparator is an inverting input and other one of the first and second inputs of the second comparator is a non-inverting input, the first input of the second comparator being of the same type as the first input of the first comparator;
a resistive circuit connected between the first input of the first comparator and the ground, wherein the resistive circuit comprises at least a first resistor;
a first capacitor charging circuit connected between the second input of the first comparator and the ground, wherein the first capacitor charging circuit comprises a first capacitor, a second resistor connected in series with the first capacitor and a first switch connected in parallel with the first capacitor; a second capacitor charging circuit connected between the second input of the second comparator and the ground, wherein the second capacitor charging circuit comprises a second capacitor, a third resistor connected in series with the second capacitor and a second switch connected in parallel with the second capacitor;
a third switch connected between the second current source and the first capacitor charging circuit;
a fourth switch connected between the third current source and the second capacitor charging circuit; and
a resetting circuit configured to control the first, second, third and fourth switches based on the outputs of the first and second comparators for enabling alternating charging of the first and second capacitors and periodic resetting of a charge of the first and second capacitors.

The first and second aspects provide the technical effect that a relaxation oscillator or a differential relaxation oscillator for generating a non-sinusoidal periodic output signal is implemented.

The first and second aspects provide the following advantages. Due to the inclusion of at least one offset resistor (i.e., the second resistor for the single-ended relaxation oscillator or the second and third resistors for the differential relaxation oscillator), the temperature-dependency of the implemented relaxation oscillator or differential relaxation oscillator is minimized in a simple but effective manner with a minimal number of required electrical components. Notably, no special resistor type (namely, resistor types enabling implementation of a negative temperature coefficient) need to be employed to flatten the temperature gradient of the relaxation oscillator or the differential relaxation oscillator.

Embodiments are defined in the dependent claims. The scope of protection sought for various embodiments is set out by the independent claims.

The embodiments and features, if any, described in this specification that do not fall under the scope of the independent claims are to be interpreted as examples useful for understanding various embodiments of the invention.

### BRIEF DESCRIPTION OF DRAWINGS

In the following, example embodiments will be described in greater detail with reference to the attached drawings, in which

FIG. 1 illustrates a relaxation oscillator according to embodiments;

FIGS. 2A and 2B illustrate, respectively, an implementation of the falling edge delay circuit according to an embodiment and exemplary input and output signals of the falling edge delay circuit;

FIGS. 3A and 3B illustrate exemplary operation of the relaxation oscillator according to an embodiment

FIG. 4 illustrates a differential relaxation oscillator according to embodiments;

FIG. 5 illustrates a process carried out by a resetting circuit of a differential relaxation oscillator according to an embodiment; and

FIG. 6 illustrates exemplary operation of the differential relaxation oscillator according to an embodiment.

### DETAILED DESCRIPTION OF SOME EMBODIMENTS

The following embodiments are only presented as examples. Although the specification may refer to “an”, “one”, or “some” embodiment(s) and/or example(s) in several locations of the text, this does not necessarily mean that each reference is made to the same embodiment(s) or example(s), or that a particular feature only applies to a single embodiment and/or example. Single features of different embodiments and/or examples may also be combined to provide other embodiments and/or examples.

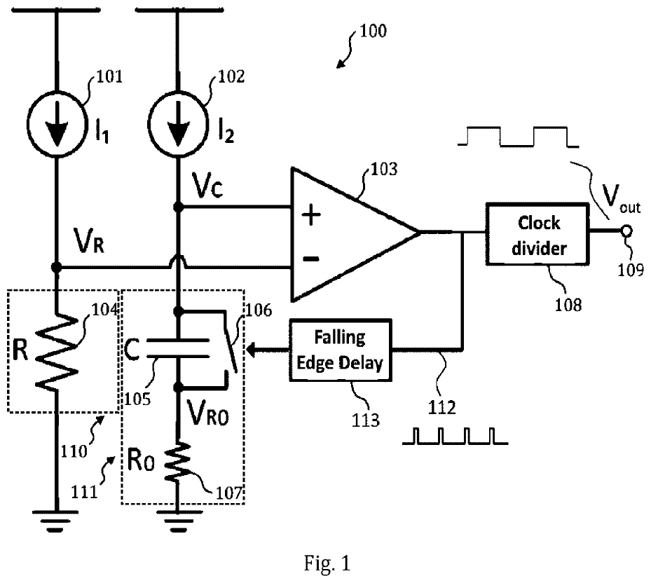

FIG. 1 illustrates a relaxation oscillator 100 (or specifically an RC relaxation oscillator) according to an embodiment for providing a flat frequency response. The relaxation oscillator 100 may be specifically an integrated relaxation oscillator (i.e., a relaxation oscillator implemented on at least one integrated circuit). For example, the relaxation oscillator 100 may be a CMOS-based integrated relaxation oscillator.

The relaxation oscillator 100 comprises a first current source 101 and a second current source 102. The first current source 101 may be configured to output a first current I₁, and the second current source may be configured to output a second current I₂. In some embodiments, the first and second currents may be (substantially) equal (i.e., I₁=I₂).

The relaxation oscillator 100 further comprises a comparator 103 having an inverting input connected to the first current source 101, a non-inverting input connected to the second current source 102 and an output 109 (corresponding to an output voltage Vₒᵤₜ). The output 109 of the comparator 103 may also correspond to an output of the relaxation oscillator 100.

The output 109 of the comparator 103 may correspond to a (binary) digital output. Specifically, the output of the comparator 103 may (at least ideally) have the following logical (binary) form:

$${V}_{o u t} = \{ \begin{matrix}1 , if {V}_{C} > {V}_{R} \\ 0 , if {V}_{C} \leq {V}_{R}\end{matrix} . \qquad ( 1 )$$

In practice, the logical ‘1’ may be associated with a first voltage (a HIGH voltage) and the logical ‘0’ may be associated with a second voltage (a LOW voltage) which is typically smaller than the first voltage.

The comparator 103 may be of any conventional type or model. The comparator 103 may be implemented, e.g., using a (high-gain) differential amplifier (e.g., an operational amplifier or a dedicated comparator chip). The gain of the differential amplifier is preferably high enough that even a very small difference between the input voltages will saturate the output and thus the output voltage will correspond to either the LOW logic voltage or the HIGH logic voltage, as described above in connection with (1).

The relaxation oscillator 100 further comprises a resistive (or resistor) circuit 110 connected between the inverting input of the comparator 103 and the ground (or equally between the output of the first current source 101 and the ground). The resistive circuit 110 comprises at least (or consists of) a first resistor 104 (or a first resistive element), as shown in FIG. 1. The first resistor 104 has a first resistance R and a first (positive) temperature coefficient α. The voltage at the node between the first current source 101 and the resistive circuit 110 (or equally between the inverting input of the comparator 103 and the resistive circuit 110) is denoted as V_{R}.

The relaxation oscillator 100 further comprises a capacitor charging circuit 111 connected between the non-inverting input of the comparator 103 and the ground (or equally between the output of the second current source 102 and the ground). The capacitor charging circuit 111 comprises (or, as shown in FIG. 1, consists of) a capacitor 105, a second resistor 107 (equally called an offset resistor) connected in series with the capacitor 105 and a switch 106 connected in parallel with the capacitor 105. The capacitor 105 has a capacitance C, the second resistor 107 has a second resistance R₀ and a second (positive) temperature coefficient α₀ and the voltage at the node between the second current source 102 and the capacitor 105 (or equally between the non-inverting input of the comparator 103 and the capacitor 105) is denoted as V_{C}. The capacitor 105 may also be associated with a third temperature coefficient though typically said third temperature coefficient has a value close to zero (and thus has negligible effect on the temperature coefficient of the relaxation oscillator 100 as a whole).

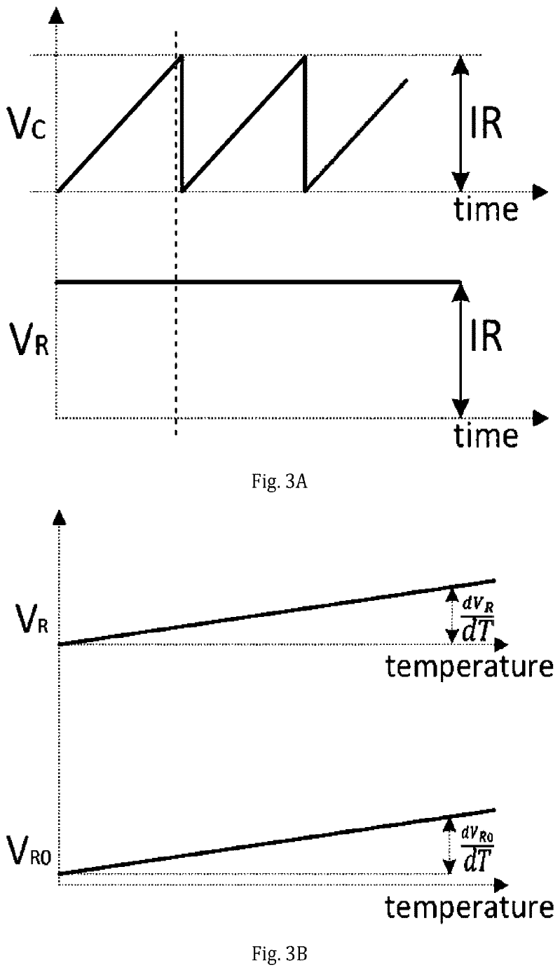

The switch 106 may be an active HIGH switch (i.e., being open when input voltage is HIGH). When the switch 106 is open, the capacitor 105 is being charged. Closing the switch 106 enables bypassing the capacitor 105 which causes the capacitor 105 to discharge. It should be noted that while the voltage V_{R} remains constant during the operation of the relaxation oscillator 100, the voltage V_{C} is constantly rising due to the charging of the capacitor when the switch is open. This charging/discharging operation is discussed in further detail in connection with FIGS. 3A and 3B.

The second resistor 107 R₀ may be used, in embodiments, specifically to compensate for the positive or negative temperature coefficient of first (sheet) resistance R. It should be noted that, without the second resistor R₀, the temperature coefficient of relaxation oscillator 100 as a whole would be highly dependent on said temperature coefficient of the first resistor 104 (R). In other words, the second resistor R₀ (i.e., the offset resistor) is included in the capacitor charging circuit 111 to offset the temperature coefficient of the first resistor R from the (adjacent) resistive circuit 110 so as to flatten the temperature gradient of the relaxation oscillator 100 as a whole.

The first and/or second resistors 104, 107 may be, for example, resistors of any of the following types (or a combination of one or more types): diffusion, well, pinched well poly and metal. In general, the first and/or second resistors 104, 107 may correspond to any elements providing resistance.

In an embodiment, the first resistor (R) 104 is a poly resistor and/or the second resistor (R₀) 107 is a diffusion resistor.

In some embodiments, the resistance R of the first resistor 104 may be larger than the resistance R₀ of the second resistor 107 or even larger than the resistance R₀ of the second resistor 107 multiplied by 2, 3, 4, 5, 6, 7 or 8. The capacitor 105 may correspond to any element providing capacitance.

Exemplary values for the capacitance C of the capacitor 105 and resistances R & R₀ of the first and second resistors 104, 107 may be, e.g., C=2.2 pF, R=6 MΩ and R₀=0.7 MΩ.

The relaxation oscillator 100 further comprises a clock divider 108. The clock divider 108 is connected to the output of the comparator 103 and provides an output clock (voltage) signal Vₒᵤₜ 109. The clock divider 108 is configured so as to ensure that output clock duty cycle is substantially 50%. In other words, the clock divider 108 is configured to output an output clock signal Vₒᵤₜ 109 having a high value substantially 50% of the time and a low value substantially 50% of the time.

In some embodiments, the clock divider 108 may be omitted from the relaxation oscillator 100 of FIG. 1. For example, it may be provided as a separate element from the relaxation oscillator 100.

If the response delay of the comparator 103 is very small, the switch 106 may be closed for too short a time to ensure complete discharge of the capacitor C 105. To avoid this, the relaxation oscillator 100 comprises a falling edge delay circuit 113. The falling edge delay circuit 113 is connected between the output of the comparator 103 and the switch 106 for enabling switching of the switch 106 based on the output of the comparator 103 in a delayed manner. Namely, the falling edge delay circuit 113 is configured so as to ensure that the capacitor 105 is completely discharged following the closing of the switch 106. In other words, the falling edge delay circuit 113 ensures that the input of the switch 106 stays HIGH (i.e., “1”) a bit longer than the output of the comparator 103 and V_{C} completely discharges to V_{R0} potential. The falling edge delay circuit 113 is discussed in more detail below.

The switching operation of the relaxation oscillator 100 may work as described in the following.

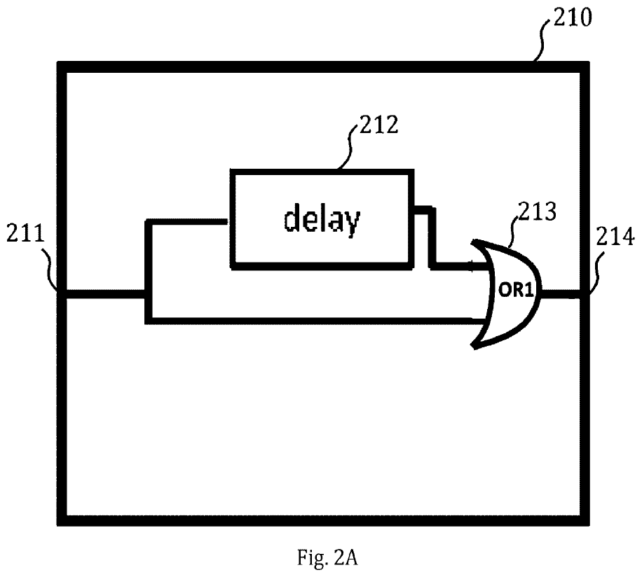

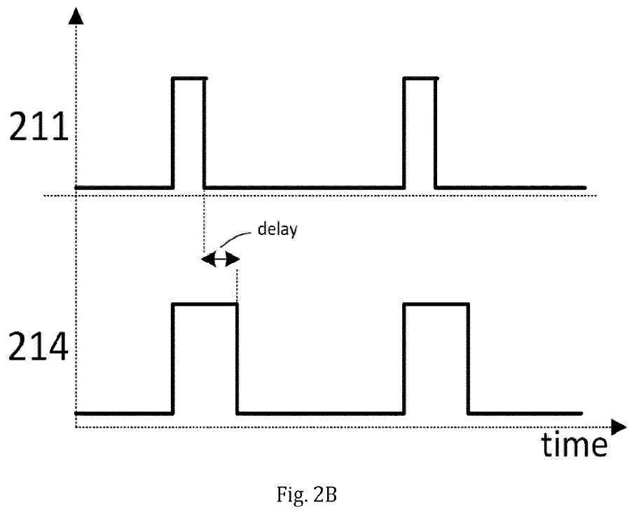

When the output of the comparator 103 indicates that the voltage V_{C} of the non-inverting input fails to exceed a voltage of the inverting input V_{R} (e.g., corresponding to binary output of 0 or LOW value), the switch 106 remains in an open position. In response to the output of the comparator 103 corresponding to a logical one (being indicative of the voltage V_{C} of the non-inverting input exceeding a voltage of the inverting input V_{R}), the switch 106 is closed, leading to discharge of the capacitor 105. This causes the voltage V_{C} to reset to VRO. When the output of the comparator 103 again indicates that the voltage V_{C} of the non-inverting input fails to exceed a voltage of the inverting input V_{R}, the switch 106 is returned to the open position which again causes charging of the capacitor 105. Due to the falling edge delay circuit 113, the opening of the switch 106 is delayed in this case, as will be described in detail in connection with FIGS. 2A and 2B.

In some embodiments, the falling edge delay circuit 113 of FIG. 1 may be omitted (i.e., the output of the comparator 103 may be connected directly to the switch 106). This may be done especially if the propagation delay resulting from the comparator 103 itself is greater than the duration associated with the discharging process or cycle of the capacitor 105 or if not being able to fully discharge the capacitor 105 can be tolerated.

In some alternative embodiments, the order of the inverting and non-inverting inputs of the comparator 103 may be reversed. Thus, the comparator 103 may have a first input connected to the first current source 101, a second input connected to the second current source 102, where one of the first and second inputs is an inverting input and the other is a non-inverting input. The resistive circuit 110 may be connected between the first input of the comparator and the ground while the capacitor charging circuit 111 may be connected between the second input of the comparator 103 and the ground. If the order of the inverting and non-inverting inputs of the comparator 103 is reversed (compared to the order shown in FIG. 1), the output of the comparator 103 may be inverted or alternatively the switch 106 may be configured to be an active low switch (i.e., being closed when input voltage is LOW).

FIG. 2A illustrates an implementation of a falling edge delay circuit 210 according to an embodiment. The falling edge delay circuit 210 of FIG. 2A may correspond to the falling edge delay circuit 113 of FIG. 1.

Referring to FIG. 2A, the falling edge delay circuit 210 has an input 211 and an output 214. The falling edge delay circuit comprises a delay element 212 connected to the input 211 and an OR gate 213 having a first input connected to the delay element 212 and a second input connected to the input 211 of the falling edge delay circuit 210 and an output connected to the output 214 of the falling edge delay circuit 210.

The falling edge delay circuit 210 works as follows. When the input 211 is equal to 0 (and has been equal to 0 for some time), the delayed signal has the same value of 0 and thus output 214 of the falling edge delay circuit 210 is also equal to 0. When the value of the input 211 of the falling edge delay circuit 210 switches from 0 to 1, the output of the OR gate 213 (and thus the output 214 of the falling edge delay circuit 210) switches also from 0 to 1 while the output 214 of the delay element 212 remains 0 for a pre-defined amount of time until also eventually switching from 0 to 1. When the value of the input 211 of the falling edge delay circuit 210 switches to 0, the output 214 of the falling edge delay circuit 210 remains 1 for a pre-defined length of time defined by the delay element 212 equivalent to falling edge delay between the input 211 and the output 214.

FIG. 2B illustrates exemplary input and output signals of the falling edge delay circuit 210 of FIG. 2A. Specifically, the input signal 211 is shown on the top half of the figure while the output signal 214 is shown on the bottom half of the figure. FIG. 2B clearly illustrates the delay operation described in the previous paragraph, that is, the falling edge of the output signal 214 is delayed by a pre-defined length of time relative to the falling edge of the input signal 211 to ensure (more) complete discharging of the capacitor of the relaxation oscillator.

In some embodiments of the relaxation oscillator described in connection with FIG. 1 (and FIGS. 2A and/or 2B), the first and second resistances R and R₀ and the first and second temperature coefficients α and do may be selected so as to implement a substantially flat temperature response for the relaxation oscillator 100 as a whole. In order to keep the temperature gradient of the relaxation oscillator 100 at zero, the following equation for the rate of change of a voltage over R (V_{R}) with temperature and a rate of change of voltage over R₀ (VRO) with temperature must hold:

$$\frac{d {V}_{R}}{d T} = \frac{d {V}_{R 0}}{d T} . \qquad ( 2 )$$

By multiplying each side of (2) with dT and applying Ohm's law based on FIG. 1, the equation may be written as

d(I·R)=d(I·R₀). (3)

It should be noted that here it assumed the first and second current source provide equal currents (I₁=I₂=I). By applying the differential to the resistance terms (the current I is assumed to be constant) and using the basic definition of the temperature coefficient (dR/R=α·dT), equation (3) may be written as

I(R(1+α·dT))=I(R₀(1+α₀·dT)). (4)

Finally, equation (4) may be reordered to give the ratio of the first and second resistances R and R₀ as:

$$\frac{R}{{R}_{0}} = \frac{( 1 + {α}_{0} \cdot dT )}{( 1 + α \cdot dT )} . \qquad ( 5 )$$

Thus, the first and second resistances R and R₀ and the associated first and second temperature coefficients α and co may be selected so as to satisfy the equation (5), at least approximately. In practice, the design process for the circuit elements of the relaxation oscillator may be proceed, for example, as follows. First, values for R, C, I₁ and I₂ may be selected to achieve a desired nominal frequency of the relaxation oscillator and a desired nominal power consumption. Then, value of R₀ may be selected based on (5) knowing the value of R and its temperature coefficient α. In order to ensure as large as possible headroom for the capacitor voltage V_{C} to charge and discharge, the resistor R₀ with the highest available temperature coefficient α₀ may be selected from the available devices of the CMOS process. As shown in (5), the higher the value of the temperature coefficient do is, lower the absolute value required for the sheet resistance R₀, and hence the biggest headroom for the capacitor C is achieved.

FIGS. 3A and 3B illustrate exemplary operation of the relaxation oscillator of FIG. 1. Namely, FIG. 3A plots voltages V_{C} (top subfigure) and V_{R} (bottom subfigure) against time while FIG. 3B plots voltages V_{R} (top subfigure) and VRO (bottom subfigure) against temperature. As shown in FIG. 1 and discussed above, the voltage V_{C} is the voltage at the node between the second current source and the capacitor (or equally between the non-inverting input of the comparator and the capacitor), the voltage V_{R} is the voltage at the node between the first current source and the first resistor (or equally between the inverting input of the comparator and the first resistor) and the voltage V_{R0} is a voltage over the (offset) resistor R₀. The horizontal axes of the subfigures of FIGS. 3A and 3B are aligned with each other.

Referring to FIG. 3A, the switch is assumed initially to just have been opened. As a result, V_{C} is initially at zero, but the capacitor of the relaxation oscillator is charging and thus V_{C} is increasing. On the other hand, V_{R} remains constant during the operation of the relaxation oscillator (irrespective of the position of the switch). The vertical dashed line in FIG. 3A indicates time at which the switch is closed. This causes the capacitor to discharge and thus V_{C} to drop to zero (while V_{R} is not changed). When value of the voltage V_{C} exceeds V_{R}, the output of the comparator 103 changes from low “0” state to high “1” state. This leads to closing of switch 106 in FIG. 1, and discharge of the capacitor C 105. Immediately following the closing of the switch, the switch is again opened and thus the capacitor is again charged (as indicated by the rising V_{C}). The length of the time that the switch 106 remains closed depends on propagation delay of the comparator 103, discharge rate of capacitor C 105 and additional delay caused by the falling edge delay circuit 113. The voltage level of V_{C} at which the switch is closed is given by V_{C}=V_{R}=RI. In other words, the switch is closed when it is detected that V_{C}>V_{R} i.e., when the output of the comparator has a value (e.g., a value corresponding to a logical one) indicating that V_{C}>V_{R}. To ensure complete discharge of the capacitor C 105 when the switch is closed, the falling edge delay circuit 113 causes the switch 106 to stay closed for a bit longer compared to a case where the input 112 would be connected directly to the switch 106. Note that capacitor C 105 discharges to V_{R0} potential, which is a product of second current source and R₀, namely V_{R0}=I₂R₀.

Referring to FIG. 3B, it is evident based on the two subfigures for V_{R} and VRO that V_{R} and VRO depend on the temperature in the same manner. Specifically, the slope (i.e., the temperature derivative) of the two curves in the two subfigures of FIG. 3B is equal. In other words, the term dV_{R}/dT is equal to dV_{R0}/dT, as indicated in FIG. 3B. This corresponds to the condition of (2) discussed above.

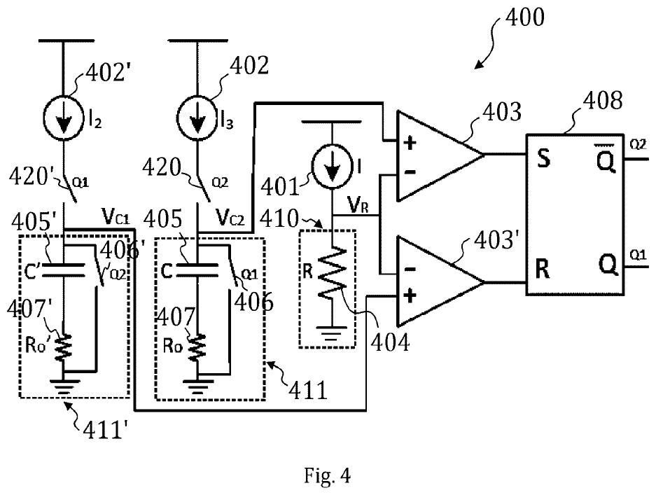

While above specifically single-ended (i.e., non-differential) relaxation oscillators according to embodiments were described in detail, in other embodiments, a differential relaxation oscillator with two offset resistors may be provided. FIG. 4 illustrates a differential relaxation oscillator 400 (or specifically a differential RC relaxation oscillator) according to an embodiment for providing a flat frequency response. The differential relaxation oscillator 400 may be specifically an integrated relaxation oscillator (i.e., a relaxation oscillator implemented on at least one integrated circuit). For example, the differential relaxation oscillator 400 may be a CMOS-based integrated relaxation oscillator.

The operation of the differential relaxation oscillator 400 is, in many ways, similar to the operation of the single-ended relaxation oscillator 100. In general, both relaxation oscillators are based on the use of offset resistor(s) arranged in series with capacitor(s). Any of the definitions provided in connection with any of FIGS. 1, 2A, 2B, 3A and 3B for the single-ended relaxation oscillator may apply, mutatis mutandis, for the differential relaxation oscillator 400 (namely, after taking into account the differential nature of the circuit 400 of FIG. 4).

In general, it should be noted that the architecture of the differential relaxation oscillator 400 closely resembles the architecture of the single-ended relation oscillator 100 of FIG. 1. The obvious difference between the two architectures is that the differential relaxation oscillator 400 comprises the two differential branches defined by elements 402′, 403′, 405′ to 407′, 411′, 420′ and elements 402, 403, 405 to 407, 411, 420, respectively. Each of said branches are, apart from the addition of the third and fourth switches 420′, 420, fully analogous with the circuit defined by elements 102, 103, 105 to 107, 111 of FIG. 1. Notably, elements 401, 403, 410 may correspond fully to elements 101, 103, 110 of FIG. 1.

It should be noted that the falling edge delay circuit 113 and the clock delay circuit 108 as used in the single-ended relaxation oscillator 100 of FIG. 1 are not necessary for operation of the differential relaxation oscillator 400 of FIG. 4. This is due to the fundamental nature of differential relaxation oscillators. Namely, as capacitors Cand C′ (elements 405 and 405′) of the differential relaxation oscillator 400 of FIG. 4 are charged and discharged alternately (as opposed to at the same time), the resetting circuit 408 works in a similar manner as the falling edge circuit 113 and the clock delay circuit 108.

The differential relaxation oscillator 400 comprises a first current source 401, a second current source 402′ and a third current source 402. The first current source 401 may be configured to output a first current I₁, the second current source may be configured to output a second current I₂ and the third current source may be configured to output a third current I₃. In some embodiments, the first, second and third currents may be (substantially) equal (i.e., I₁=I₂=I₃).

The relaxation oscillator 400 further comprises a first comparator 403′ having an inverting input connected to the first current source 401, a non-inverting input connected to the second current source 402′ and an output. Moreover, the relaxation oscillator 400 comprises a second comparator 403 having an inverting input connected to the first current source 401, a non-inverting input connected to the third current source 402 and an output. The outputs of the first and second comparators 403′, 403 may also correspond to outputs of the relaxation oscillator 400. The first and second comparators 403′, 403 may be defined as discussed above for the comparator 103 of FIG. 1.

Similar to the relaxation oscillator 100 of FIG. 1, the differential relaxation oscillator 400 comprises a resistive (or resistor) circuit 410 connected between the inverting input of the first comparator 403′ (or equal of the second comparator 403) and the ground. The resistive circuit 410 comprises at least (or, as in FIG. 4, exclusively) a first resistor 404. The first resistor 404 has a first resistance R and a first temperature coefficient α. The first resistor 404 may defined as described for the first resistor 104 of FIG. 1. The voltage at the node between the first current source 401 and the resistive circuit 410 (or equally between the inverting input of the first or second comparator 403′, 403 and the resistive circuit 410) is denoted as V_{R}, similar to FIG. 1.

The relaxation oscillator 400 further comprises a first capacitor charging circuit 411′ connected between the non-inverting input of the first comparator 403′ and the ground (or equally between the output of the second current source 402′ and the ground). The first capacitor charging circuit 411′ comprises (or, as shown in FIG. 4, consists of) a first capacitor 405′, a second resistor 407′ (equally called a first offset resistor) connected in series with the first capacitor 405′ and a first switch 406′ connected in parallel with the first capacitor 405′. The first capacitor 405′ has a first capacitance C′, the second resistor 407′ has a second resistance R₀′ and a second temperature coefficient do′ and the voltage at the node between the second current source 402′ and the first capacitor 405′ (or equally between the non-inverting input of the first comparator 403′ and the first capacitor 405′) is denoted as V_{C1}.

Moreover, the relaxation oscillator 400 further comprises a second capacitor charging circuit 411 defined in a similar manner as the first capacitor charging circuit 411′. Namely, the second capacitor charging circuit 411 is connected between the non-inverting input of the second comparator 403 and the ground (or equally between the output of the third current source 402 and the ground). The second capacitor charging circuit 411 comprises (or, as shown in FIG. 4, consists of) a second capacitor 405, a third resistor 407 (equally called a second offset resistor) connected in series with the second capacitor 405 and a second switch 406 connected in parallel with the second capacitor 405. The second capacitor 405 has a second capacitance C, the third resistor 407 has a third resistance R₀ and a third temperature coefficient do and the voltage at the node between the third current source 402 and the second capacitor 405 (or equally between the non-inverting input of the second comparator 403 and the second capacitor 405) is denoted as V_{C2}.

The first and second capacitors 405′, 405 may also be associated with a fourth and fifth temperature coefficients though typically said fourth and fifth temperature coefficients have a value close to zero (and thus have negligible effect on the temperature coefficient of the relaxation oscillator 400 as a whole).

In contrast to the relaxation oscillator 100 of FIG. 1, the differential relaxation oscillator 400 further comprises third and fourth switches 420′, 420 arranged between the second current source 402′ and the first capacitor charging circuit 411′ and between the third current source 402 and the second capacitor charging circuit 411, respectively.

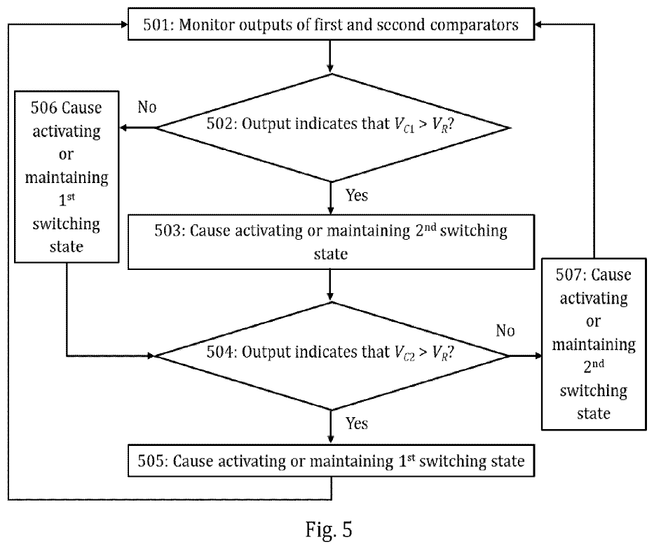

Finally, the differential relaxation oscillator 400 comprises a resetting circuit 408 (e.g., a latch) configured to control the first, second, third and fourth switches 406′, 406, 420′, 420 based on the outputs of the first and second comparators 403′, 403 for enabling alternating charging of the first and second capacitors 405′, 405 and periodic resetting of a charge of the first and second capacitors 405′, 405 (while the other one of the first and second capacitors 405′, 405 is charging), as will be discussed in detail in connection with FIGS. 5A and 5B. The resetting circuit 408 may be configured to control the first, second, third and fourth switches 406′, 406, 420′, 420 so that, at any given time, the state (i.e., open/close state) of the third switch 420′ matches the state of the second switch 406 and the state of the fourth switch 420 matches the state of the first switch 406′. Thus, at any given time, only two of the first, second, third and fourth switches 406′, 406, 420′, 420 are closed (or open).

In FIG. 4, the resetting circuit 408 corresponds specifically to an SR (set-reset) latch (or flip-flop). The SR latch 408 has a reset (R) input connected to an output of the first comparator 403 and a set(S) input connected to an output of the second comparator 403′. Moreover, the SR latch has a Q output (equally called a second output or a Q2 output) connected to (and controlling) the first and fourth switches 406′, 420 and a Q output (equally called a first output or a Q1 output) connected to (and controlling) the second and third switches 406, 420′. Both input and outputs are logical (binary) inputs, and both outputs are logical (binary) outputs. The first, second, third and fourth switches 406′, 406, 420′, 420 may be configured to be open when a logical zero is received and closed when a logical one is received. The SR latch 408 may have the following truth table:

| R | S | Q̅ = Q2 | Q = Q1 |
|---|---|---|---|
| 0 | 0 | No change | No change |
| 1 | 0 | 1 | 0 |
| 0 | 1 | 0 | 1 |
| 1 | 1 | 0 | 0 |

Here, the logical ‘1’ of Q1 may be associated with a first voltage (a HIGH voltage) and the logical ‘0’ of Q2 may be associated with a second voltage (a LOW voltage) which is typically smaller than the first voltage. Similarly, the logical ‘1’ of Q2 may be associated with a third voltage (a HIGH voltage) and the logical ‘0’ of Q2 may be associated with a fourth voltage (a LOW voltage) which is typically smaller than the third voltage. The first and third voltages may or may not be equal. The second and fourth voltages may or may not be equal.

It should be noted that the cases R=S=0 & R=1=1 are not possible under normal operating conditions of the differential relaxation oscillator 400 (i.e., unless there is a fault in the operation of the differential relaxation oscillator 400).

In some embodiments, the second resistance R₀′ may be equal to the third resistance R₀. Additionally or alternatively, the first capacitance C′ may be equal to the second capacitance C.

In some embodiments, the first, second and third temperature coefficients α, α₀′ and α₀ are either all positive or all negative.

In some embodiments of the differential relaxation oscillator of FIG. 4 (and FIG. 5), the first, second and third resistances R, R₀′ and R₀ and the first, second and third temperature coefficients α, α₀′ and α₀ may be selected so as to implement a substantially flat temperature response for the differential relaxation oscillator 100 as a whole. The equations (2)-(5) written for R and R₀ of FIG. 1 apply, mutatis mutandis, separately for both R and R₀ of FIG. 4 and R and R₀′ of FIG. 4.

Similar to as described for the single-ended relaxation oscillator 100 of FIG. 1, the order of the inverting and non-inverting inputs of the first and second comparators 403, 403′ may be reversed. Thus, the first comparator 403 may have a first input connected to the first current source 401, a second input connected to the third current source 402, where one of the first and second inputs of the first comparator 403 is an inverting input and other one of the first and second inputs of the first comparator 403 is a non-inverting input. Furthermore, the second comparator 403′ may have a first input connected to the first current source 401, a second input connected to the second current source 402′, where one of the first and second inputs of the second comparator 403′ is an inverting input and other one of the first and second inputs of the second comparator 403′ is a non-inverting input. The first input of the second comparator 403′ may be assumed to be of the same type (i.e., inverting or non-inverting type) as the first input of the first comparator 403. If the order of the inverting and non-inverting inputs of the first and second comparators 403, 403′ is reversed (compared to the order shown in FIG. 4), the outputs of the first and second comparators 403, 403′ may be inverted or alternatively the first and second switches 406, 406′ may be configured to be an active low switch (i.e., being closed when input voltage is LOW).

FIG. 5 illustrates a process carried out by a resetting circuit of a differential relaxation oscillator according to an embodiment. The resetting circuit carrying out the illustrated process may correspond to the resetting circuit 408 of the differential relaxation oscillator 400 of FIG. 4. Said process may be performed by the resetting circuit in software (i.e., using computer software maintained in at least one memory of the resetting circuit and defining steps to be executed by at least one processor of the resetting circuit) or in hardware (i.e., using hardware circuitry such as a latch) or using a combination of hardware and software.

It is assumed, in the following discussion, that that the first and fourth switches (elements 406′ and 420) are initially open and the second and third switches (elements 406 and 420′) are initially closed. This is called in the following a first switching state. The first switching state may correspond logical outputs Q1=1 & Q2=0. An opposite switching state, i.e., the case where the first and fourth switches (elements 406′ and 420) are closed and the second and third switches (elements 406 and 420′) are open is called in the following a second switching state. The second switching state may correspond logical outputs Q1=0 & Q2=1. The first and second switching states are mutually exclusive (i.e., only one of them may be active at any given time).

The resetting circuit monitors, in block 501, an output of the first comparator (element 403′) and an output of the second comparator (element 403) or specifically the output voltages thereof. The resetting circuit checks, in block 502, whether the output of the first comparator indicates that a voltage V_{C1} of the non-inverting input of the first comparator exceeds a voltage of the inverting input V_{R}. This may correspond, for example, to checking whether the output of the first comparator is equal to a logical one (indicating that V_{C}>V_{R}) or equal to a logical zero (indicating that V_{C}≤V_{R}). It should be noted that while the voltage V_{R} remains constant during the operation of the differential relaxation oscillator, the voltage V_{C1} is constantly rising due to the charging of the first capacitor when the first switch (element 406′) is open and the third switch (element 420′) is closed (i.e., when the first switching state is activated).

In response to the output of the comparator indicating that the voltage V_{C1} of the non-inverting input of the first comparator fails to exceed a voltage of the inverting input V_{R} in block 502 (e.g., corresponding to a logical output of 0), the resetting circuit maintains, in block 506, the first, second, third and fourth switches in the first switching state.

In response to the output of the first comparator corresponding to a logical one (being indicative of the voltage V_{C} of the non-inverting input exceeding a voltage of the inverting input V_{R} in block 502), the resetting circuit causes, in block 503, activation of the second switching state so as to discharge the first capacitor. This causes the voltage V_{C1} to drop to zero.

The resetting circuit also carries out, in block 504, 505, 507, a corresponding process based on the output of the second comparator (element 403). Namely, the resetting circuit checks, in block 504, whether the output of the second comparator indicates that a voltage V_{C2} of the non-inverting input of the second comparator exceeds a voltage of the inverting input V_{R}. This may correspond, for example, to checking whether the output of the second comparator is equal to a logical one (indicating that V_{C}>V_{R}) or equal to a logical zero (indicating that V_{C}≤V_{R}). It should be noted that the voltage V_{C2} is constantly rising due to the charging of the second capacitor when the second switch (element 406) is open and the fourth switch (element 420) is closed (i.e., when the second switching state is activated).

In response to the output of the second comparator indicating that the voltage V_{C2} of the non-inverting input of the second comparator fails to exceed a voltage of the inverting input V_{R} in block 506 (e.g., corresponding to a logical output of 0), the resetting circuit maintains, in block 507, the first, second, third and fourth switches in the second switching state.

In response to the output of the second comparator corresponding to a logical one (being indicative of the voltage V_{C} of the non-inverting input exceeds a voltage of the inverting input V_{R} in block 504), the resetting circuit causes, in block 505, activation of the first switching state so as to discharge the second capacitor. This causes the voltage V_{C2} to drop to zero.

Following execution of block 505 or 507, the process proceeds back to block 501. In other words, the process is repeated.

Thus, as may be observed from FIG. 5, the resetting circuit is configured to activate in turns the first and second switching states so that the first and second capacitors may be charged and discharged periodically. It should be noted that only one of the first and second capacitor is charging at any given time. While one of the first and second capacitors is charging, the other of the first and second capacitors (and the associated differential branch) is in a discharged state.

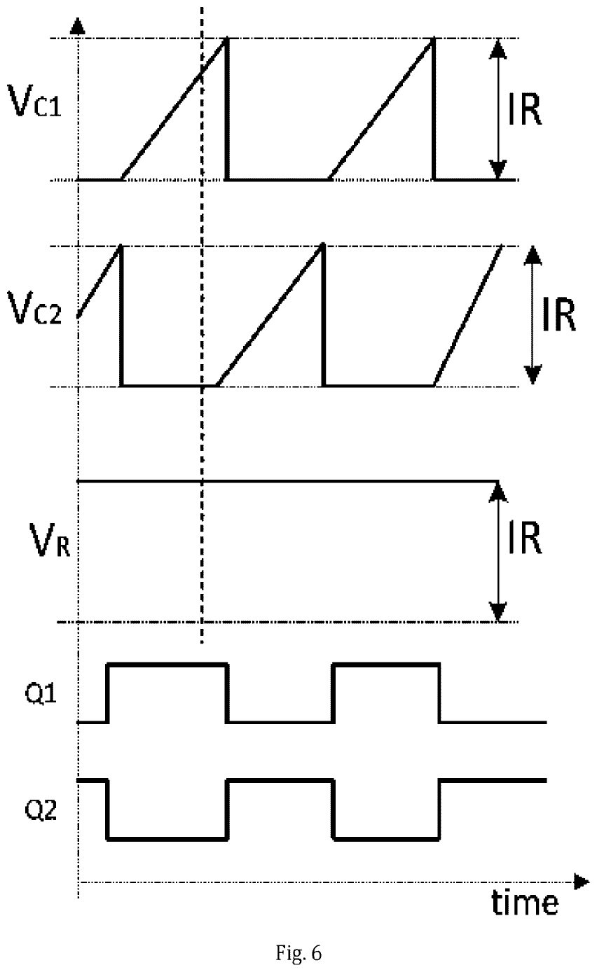

FIG. 6 illustrates exemplary operation of the differential relaxation oscillator of FIG. 4. Namely, FIG. 6 plots voltages V_{C1}, V_{C2}, V_{R}, Q1 and Q2 against time. As shown in FIG. 4 and discussed above, the voltage V_{C1} is the voltage at the node between the second current source 402′ and the first capacitor 405′ (or equally between the non-inverting input of the first comparator 403′ and the first capacitor 405′), the voltage V_{C2} is the voltage at the node between the third current source 402 and the second capacitor 405 (or equally between the non-inverting input of the second comparator 403 and the second capacitor 405), the voltage V_{R} is the voltage at the node between the first current source 401 and the first resistor 404 (or equally between the inverting input of the first/second comparator and the first resistor 404). The subfigures of FIG. 6 share the same horizontal axis.

Referring to FIG. 6, the first and fourth switches 406′, 420 are initially closed while the second and third switches 406, 420′ are open (i.e., the second switching state is active). As a result, V_{C1} is initially at zero while V_{C2} is non-zero and rising (i.e., the second capacitor is charging). This corresponds to a case where Q1 has a LOW value (corresponding to a logical zero) and Q2 has a HIGH value (corresponding to a logical one). On the other hand, V_{R} remains constant during the operation of the differential relaxation oscillator (irrespective of the position of the first, second, third and fourth switches), similar to FIG. 3A.

When V_{C2} exceeds V_{R} (=RI), the first switching state is activated (and thus the second switching state is deactivated) which, in turn, causes charging of the first capacitor (as evidenced by rising V_{C1}) and discharging of the second capacitor (as evidenced by V_{C2} going to zero). This corresponds to a case where Q1 has a HIGH value (corresponding to a logical one) and Q2 has a LOW value (corresponding to a logical zero).

Similarly, when V_{C1} exceeds V_{R} (=RI), the second switching state is again activated (and thus the first switching state is deactivated) which, in turn, causes again charging of the second capacitor (as evidenced by rising V_{C2}) and discharging of the first capacitor (as evidenced by V_{C1} going to zero). This corresponds to a case where Q1 has a LOW value (corresponding to a logical zero) and Q2 has a HIGH value (corresponding to a logical one). The operation described above is then repeated.

While FIG. 3B was discussed above in relation to the single-ended relaxation oscillator 100 of FIG. 1, FIG. 3B may equally be seen to depict the behavior of the differential relaxation oscillator 400 of FIG. 4. Further, the voltage V_{R0}′ shown in FIG. 4 may exhibit the same temperature-dependent behavior as depicted for V_{R0} in FIG. 3B.

The embodiments provide at least the following advantages.

Simplicity and low cost: The inclusion of an offset resistor R₀ in the relaxation oscillator enables overcoming the aforementioned problem relating to the positive temperature coefficient of the sheet resistance of the relaxation oscillator in a simple and cost-effective manner. For example, no special resistor type (namely, resistor types enabling implementation of a negative temperature coefficient) need to be employed to flatten the temperature gradient of the relaxation oscillator. A typical CMOS process does not offer resistors with negative temperature coefficients. In some CMOS processes, such resistors may be available though they require additional masks to be applied during production in the CMOS process which makes the manufacturing process more complex and expensive. Moreover, making the first and second current sources identical (i.e., setting I₁=I₂=I) for the single-ended relaxation oscillator or making the first, second and third current sources equal (i.e., setting I₁=I₂=I₃=I) for the differential relaxation oscillator enables obtaining a better duty cycle and a more reliable clock. Temperature compensation by inclusion of an offset resistor R₀ is simpler, and requires fewer electrical components to implement than other compensation techniques.

Reliability: The first and second resistors R and R₀ for the single-ended relaxation oscillator or all of the first, second and third resistors R, R₀′ and R₀ for the differential relaxation oscillator can be placed close to each other to obtain good matching. Similar or same resistor types may be chosen to obtain process correlation.

Embodiments described herein are applicable to systems defined above but also to other systems. The specifications of the systems and their elements develop rapidly. Such development may require extra changes to the described embodiments. Therefore, all words and expressions should be interpreted broadly and they are intended to illustrate, not to restrict, the embodiment. It will be obvious to a person skilled in the art that, as technology advances, the inventive concept can be implemented in various ways. Embodiments are not limited to the examples described above but may vary within the scope of the claims.

1. A relaxation oscillator comprising:
first and second current sources;
a comparator having a first input connected to the first current source, a second input connected to the second current source and an output, wherein one of the first and second inputs is an inverting input and other one of the first and second inputs is a non-inverting input;
a resistive circuit connected between the first input of the comparator and the ground, wherein the resistive circuit comprises at least a first resistor; and
a capacitor charging circuit connected between the second input of the comparator and the ground, wherein the capacitor charging circuit comprises a capacitor, a second resistor connected in series with the capacitor and a switch connected in parallel with the capacitor, the switch being configured to be controlled based on the output of the comparator.

2. The relaxation oscillator according to claim 1, further comprising:
a falling edge delay circuit connected between the output of the comparator and the switch for delaying switching of the switch so as to enable more complete resetting of a charge of the capacitor when the switch is closed.

3. The relaxation oscillator according to claim 1, further comprising:
a clock divider circuit connected to the output of the comparator.

4. The relaxation oscillator according to claim 1, wherein the first and second current sources are configured to output substantially equal currents.

5. The relaxation oscillator according to claim 1, wherein the first and second resistors have, respectively, first and second resistances and, respectively, first and second temperature coefficients selected so as to implement a substantially flat temperature response for the relaxation oscillator as a whole.

6. The relaxation oscillator according to claim 5, wherein the first and second temperature coefficients are both either positive or negative and/or the first resistance is larger than the second resistance and the second temperature coefficient is larger than the first temperature coefficient.

7. The relaxation oscillator according to claim 5, wherein the first resistance, the second resistance, the first temperature coefficient and the second temperature coefficient have values substantially satisfying
$$\frac{R}{{R}_{0}} = \frac{( 1 + {α}_{0} \cdot dT )}{( 1 + α \cdot dT )} ,$$
where R, R₀, α and α₀ are, respectively, the first resistance, the second resistance, the first temperature coefficient and the second temperature coefficient and dT is a differential of temperature.

8. The relaxation oscillator according to claim 1, wherein the falling edge delay circuit comprises
an input,
an output,
a delay element having an input connected to the input of the falling edge delay circuit and an output and
an OR gate having a first input connected to an output of the delay element, a second input connected to the input of the falling edge delay circuit and an output connected to the output of the falling edge delay circuit.

9. A differential relaxation oscillator comprising:
first, second and third current sources;
a first comparator having a first input connected to the first current source, a second input connected to the third current source and an output, wherein one of the first and second inputs of the first comparator is an inverting input and other one of the first and second inputs of the first comparator is a non-inverting input;
a second comparator having a first input connected to the first current source, a second input connected to the second current source and an output, wherein one of the first and second inputs of the second comparator is an inverting input and other one of the first and second inputs of the second comparator is a non-inverting input, the first input of the second comparator being of the same type as the first input of the first comparator;
a resistive circuit connected between the first input of the first comparator and the ground, wherein the resistive circuit comprises at least a first resistor;
a first capacitor charging circuit connected between the second input of the first comparator and the ground, wherein the first capacitor charging circuit comprises a first capacitor, a second resistor connected in series with the first capacitor and a first switch connected in parallel with the first capacitor;
a second capacitor charging circuit connected between the second input of the second comparator and the ground, wherein the second capacitor charging circuit comprises a second capacitor, a third resistor connected in series with the second capacitor and a second switch connected in parallel with the second capacitor;
a third switch connected between the second current source and the first capacitor charging circuit;
a fourth switch connected between the third current source and the second capacitor charging circuit; and
a resetting circuit configured to control the first, second, third and fourth switches based on the outputs of the first and second comparators for enabling alternating charging of the first and second capacitors and periodic resetting of a charge of the first and second capacitors.

10. The differential relaxation oscillator according to claim 9, wherein the resetting circuit is configured to control the first, second, third and fourth switches so that, at any given time, a state of the third switch matches a state of the second switch and a state of the fourth switch matches a state of the first switch.

11. The differential relaxation oscillator according to claim 9, wherein the resistive circuit consists of the first resistor, the first capacitor charging circuit consists of the first capacitor, the second resistor and the first switch and/or the second capacitor charging circuit consists of the second capacitor, the third resistor and the second switch.

12. The differential relaxation oscillator according to claim 9, wherein the first, second and third current sources are configured to output substantially equal currents.

13. The differential relaxation oscillator according to claim 9, wherein the first, second and third resistors have, respectively, first, second and third resistances and, respectively, first, second and third temperature coefficients selected so as to implement a substantially flat temperature response for the differential relaxation oscillator as a whole.

14. The differential relaxation oscillator according to claim 13, wherein the first, second and third temperature coefficients are all either positive or negative and/or the first resistance is larger than the second resistance and larger than the third resistance and the second and third temperature coefficients are larger than the first temperature coefficient.

15. The differential relaxation oscillator according to claim 9, wherein the resetting circuit is configured to:
receive the outputs of the first and second comparators;
cause closing the first and third switches in response to the output of the first comparator corresponding to a first logical value, wherein the first logical value is equal to a logical one or a logical zero;
cause opening the first and third switches or keeping the first and third switches open in response to the output of the first comparator corresponding to a second logical value, wherein the second logical value is an opposite logical value to the first logical value;
cause closing the second and fourth switches or keeping the first and third switches closed in response to the output of the second comparator corresponding to the first logical value; and
cause opening the second and fourth switches or keeping the second and fourth switches open in response to the output of the second comparator corresponding to the second logical value.
